(19) United States
(12) Patent Application Publication
(10) Pub. No.: US 2026/0031801 A1
(43) Pub. Date: Jan. 29, 2026

(54) BUFFER CIRCUIT AND IMAGING DEVICE

(71) Applicant: SONY SEMICONDUCTOR SOLUTIONS CORPORATION, Kanagawa (JP)

(72) Inventor: Yuken YAKUSHIJI, Fukuoka (JP)

(73) Assignee: SONY SEMICONDUCTOR SOLUTIONS CORPORATION, Kanagawa (JP)

(21) Appl. No.: 18/994,523

(22) PCT Filed: Jun. 19, 2023
(86) PCT No.: PCT/JP2023/022641

§ 371 Date: Jan. 14, 2025

(30) Foreign Application Priority Data
Jul. 25, 2022 (JP) 2022-117852

(51) Int. Cl. H03K 4/90; H03K 4/48; H03K 19/0185; H04N 25/709; H04N 25/78

(52) U.S. Cl. CPC H03K 4/90; H03K 4/48; H03K 19/018507; H04N 25/709; H04N 25/78

(57) ABSTRACT

Provided is a buffer circuit that can realize a wide dynamic range, a reduced area, and a reduced power consumption amount while maintaining low output impedance. The buffer circuit includes a first transistor, a current source, a second transistor, an output terminal, and first and second capacitors. The first transistor has a gate to which an input signal is input. The current source is connected to one terminal of the first transistor. The second transistor is connected to the other terminal of the first transistor. The output terminal is connected to the one terminal or the other terminal of the first transistor. The first and second capacitors are between the current source and the gate of the second transistor. The first transistor, the second transistor, and the first capacitor form a first feedback circuit. The first transistor, the current source, and the second capacitor form a second feedback circuit.

### TECHNICAL FIELD

The technology according to the present disclosure (present technology) relates to a buffer circuit and an imaging device including the buffer circuit.

### BACKGROUND ART

In an imaging device, a pixel signal read from a pixel has been typically converted from an analog signal into a digital signal by a column analog-digital converter, and subjected to signal processing by a digital signal processor (DSP). For the column analog/digital converter, a ramp signal source follower circuit has been used. For the ramp signal source follower circuit, a buffer circuit advantageous to various characteristic improvements has been desired. Thus, a flipped voltage follower circuit (hereinafter, referred to as an FVF circuit) has been known as a buffer circuit that can realize low output impedance.

However, since the FVF circuit can operate only in a limited voltage range, there is a problem that circuits that can be used for applications are also limited. For example, applying the FVF circuit to the ramp signal source follower circuit can be expected to lead to various characteristic improvements. However, the FVF circuit cannot be applied, because the ramp signal source follower circuit is required to have a wide dynamic range due to the specifications of the imaging device.

The buffer circuit described in Patent Literature 1 is a buffer circuit of a multi-stage configuration in which a common-source amplifier circuit is used. Therefore, the configuration is complicated, so that the circuit area increases and moreover the power consumption also increases.

### CITATION LIST

### Patent Document

Patent Document 1: WO2006/132315

### SUMMARY OF THE INVENTION

### Problems to be Solved by the Invention

For a while, there has been a strong demand for a buffer circuit that can realize a wide dynamic range and further can achieve a reduction in area and a reduction in power consumption.

The present disclosure has been made in view of such circumstances, and an object of the present disclosure is to provide a buffer circuit and an imaging device that can realize a wide dynamic range and can achieve a reduction in area and a reduction in power consumption while maintaining low output impedance.

### Solutions to Problems

An aspect of the present disclosure is a buffer circuit including: a first transistor having a gate to which an input signal is input; a current source connected to one terminal of the first transistor; a second transistor connected to another terminal of the first transistor; an output terminal connected to the one terminal or the another terminal of the first transistor; and first and second capacitors provided between the current source and a gate of the second transistor, the first transistor, the second transistor, and the first capacitor forming a first feedback circuit, the first transistor, the current source, and the second capacitor forming a second feedback circuit.

Another aspect of the present disclosure is an imaging device including: a pixel array unit including a plurality of pixels allowed to generate a pixel signal according to light incident from outside; a buffer circuit; a signal processing unit that compares an output signal of the buffer circuit with a pixel signal output from each of the plurality of pixels and generates image data on the basis of a comparison result; and a power supply circuit that supplies power necessary for operation of each of the pixel array unit, the buffer circuit, and the signal processing unit, the buffer circuit including: a first transistor having a gate to which an input signal is input; a current source connected to one terminal of the first transistor; a second transistor connected to another terminal of the first transistor; an output terminal connected to the one terminal or the another terminal of the first transistor; and first and second capacitors provided between the current source and a gate of the second transistor, the first transistor, the second transistor, and the first capacitor forming a first feedback circuit, the first transistor, the current source, and the second capacitor forming a second feedback circuit.

### BRIEF DESCRIPTION OF DRAWINGS

FIG. 1 is a block diagram illustrating an example of the schematic configuration of an imaging device according to a first embodiment of the present disclosure.

FIG. 2 is a block diagram for explaining an example of an image signal reading mechanism in the imaging device according to the first embodiment of the present disclosure.

FIG. 3 is a circuit diagram (part 1) illustrating the configuration of a ramp signal buffer circuit according to the first embodiment of the present disclosure.

FIG. 4 is a circuit diagram (part 2) illustrating the configuration of the ramp signal buffer circuit according to the first embodiment of the present disclosure.

FIG. 5 is a diagram for illustrating a change in a voltage Vfb between a first capacitor and a second capacitor in a case where a second feedback circuit is not formed.

FIG. 6 is a diagram for illustrating a change in the voltage Vfb between the first capacitor and the second capacitor in a case where the second feedback circuit is formed.

FIG. 7 is a circuit diagram illustrating the configuration of a ramp signal buffer circuit according to a second embodiment of the present disclosure.

FIG. 8 is a circuit diagram illustrating the configuration of a power supply circuit and a ramp signal buffer circuit according to a third embodiment of the present disclosure.

FIG. 9 is a circuit diagram illustrating the configuration of a ramp signal buffer circuit according to a fourth embodiment of the present disclosure.

FIG. 10 is a circuit diagram illustrating the configuration of a ramp signal buffer circuit according to a fifth embodiment of the present disclosure.

FIG. 11 is a circuit diagram illustrating the configuration of a ramp signal buffer circuit according to a sixth embodiment of the present disclosure.

FIG. 12 is a circuit diagram illustrating the configuration of a ramp signal buffer circuit according to a seventh embodiment of the present disclosure.

FIG. 13 is a circuit diagram illustrating the configuration of a ramp signal buffer circuit according to an eighth embodiment of the present disclosure.

FIG. 14 is a block diagram illustrating a configuration example of an imaging system as an electronic apparatus to which the present technology is applied.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs to avoid the description from being redundant.

Note that the effects described in the present specification are merely examples and are not limited, and other effects may be provided.

### First Embodiment

### Overall Configuration of Imaging Device

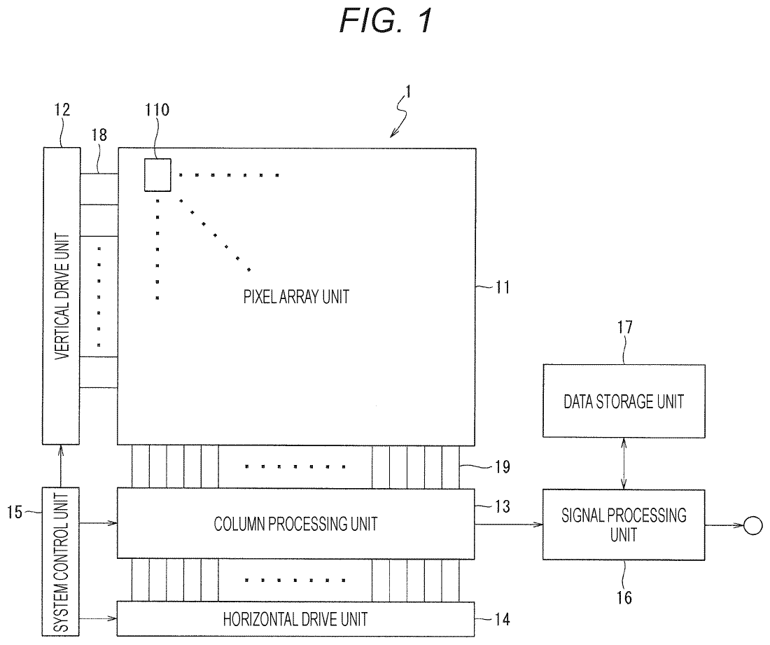

FIG. 1 is a block diagram illustrating an example of the schematic configuration of an imaging device according to a first embodiment of the present disclosure. An imaging device 1 is a semiconductor device that converts a charge amount corresponding to the intensity of light formed as an image on each pixel into an electric signal, using a photoelectric conversion element such as a photodiode constituting each pixel, and outputs the electric signal as image data, and is configured as, for example, a CMOS image sensor. The imaging device 1 can be integrally configured as, for example, a system on a chip (SoC) such as a CMOS LSI, but for example, some components described below may be configured as separate LSIs.

As illustrated in the figure, the imaging device 1 includes, for example, components such as a pixel array unit 11, a vertical drive unit 12, a column processing unit 13, a horizontal drive unit 14, a system control unit 15, a signal processing unit 16, and a data storage unit 17.

The pixel array unit 11 includes a photoelectric conversion element group such as photodiodes forming pixels 110 arrayed in a horizontal direction (row direction) and a vertical direction (column direction). The pixel array unit 11 converts a charge amount corresponding to the intensity of incident light formed as an image on each pixel 110 into an electric signal and outputs the electric signal as a pixel signal.

The vertical drive unit 12 includes a shift register, an address decoder, and the like. The vertical drive unit 12 supplies a drive signal and the like to each pixel 110 via a plurality of pixel drive lines 18, thereby driving each pixel 110 of the pixel array unit 11, for example, simultaneously or row by row.

The column processing unit 13 reads a pixel signal from each pixel via a vertical signal line (VSL) 19 for each pixel column of the pixel array unit 11, and performs noise removal processing, correlated double sampling (CDS) processing, analog-to-digital (A/D) conversion processing, and the like. The pixel signal processed by the column processing unit 13 is output to the signal processing unit 16.

The horizontal drive unit 14 includes a shift register, an address decoder, and the like. The horizontal drive unit 14 sequentially selects the pixels 110 corresponding to the pixel columns of the column processing unit 13. When selective scanning is thus performed by the horizontal drive unit 14, the pixel signals subjected to the signal processing for each pixel 110 in the column processing unit 13 are sequentially output to the signal processing unit 16.

The system control unit 15 includes a timing generator that generates various timing signals, and the like. The system control unit 15 performs drive control of the vertical drive unit 12, the column processing unit 13, and the horizontal drive unit 14 on the basis of, for example, a timing signal generated by the timing generator not illustrated in the figure.

The signal processing unit 16 performs signal processing such as arithmetic processing on the pixel signals supplied from the column processing unit 13 while temporarily storing data in the data storage unit 17 as necessary, and outputs an image signal based on each pixel signal.

Note that the imaging device 1 to which the present technology is applied is not limited to the above-described configuration. For example, the imaging device 1 may be configured such that the data storage unit 17 is disposed at a subsequent stage of the column processing unit 13, and the pixel signals output from the column processing unit 13 are supplied to the signal processing unit 16 via the data storage unit 17. Alternatively, the imaging device 1 may be configured such that the column processing unit 13, the data storage unit 17, and the signal processing unit 16 connected in cascade process the respective pixel signals in parallel.

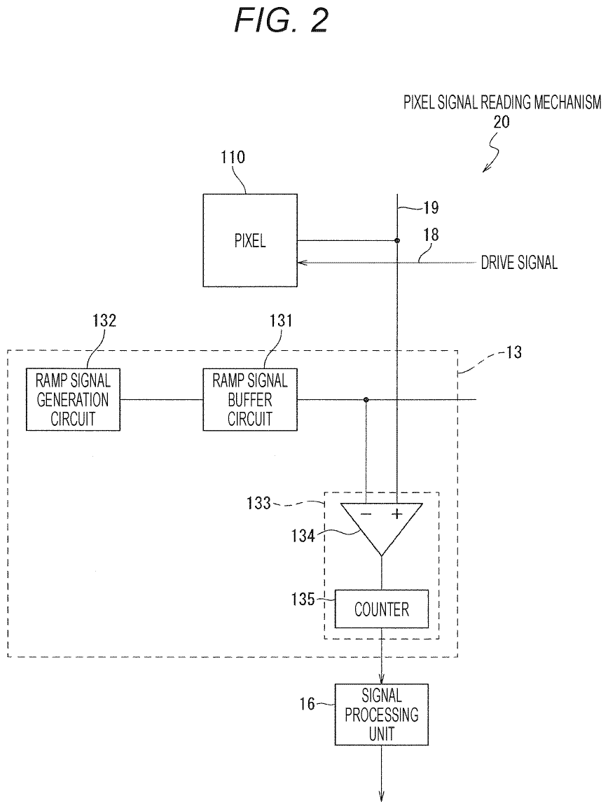

FIG. 2 is a block diagram for explaining an example of an image signal reading mechanism in the imaging device according to the first embodiment of the present disclosure. In the figure, a pixel signal reading mechanism 20 from one pixel 110 in one pixel column is exemplarily illustrated.

The figure illustrates a ramp signal buffer circuit 131, a ramp signal generation circuit 132, and an analog/digital converter (hereinafter, referred to as an AD converter) 133 as the configuration of the column processing unit 13.

The ramp signal generation circuit 132 generates and outputs a ramp signal necessary for AD conversion processing by the AD converter 133. The ramp signal is, for example, a signal whose voltage level changes in a slope over time. The ramp signal buffer circuit 131 performs impedance conversion processing on the ramp signal output from the ramp signal generation circuit 132.

The AD converter 133 converts a pixel signal in an analog format output from the pixel 110 into a pixel signal (pixel data) in a digital format. The AD converter 133 is provided in parallel for each of the vertical signal lines 19 corresponding to the pixel columns. In addition, the AD converter 133 includes a comparator 134 and a counter 135. That is, the AD converter 133 performs counting by the counter 135 while comparing a ramp signal output from the ramp signal buffer circuit 131 with a pixel signal read from the pixel 110 by the comparator 134 over time, and outputs the counted value to the signal processing unit 16 as a pixel signal in a digital format.

### Configuration of Ramp Signal Buffer Circuit

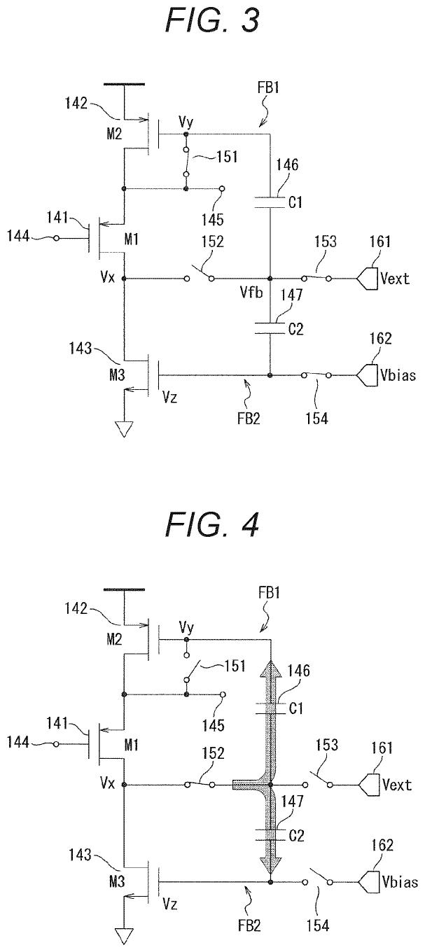

FIGS. 3 and 4 are circuit diagrams illustrating the configuration of the ramp signal buffer circuit 131 according to the first embodiment of the present disclosure. FIG. 3 is a circuit diagram illustrating the configuration of the ramp signal buffer circuit 131 in a reset mode, and FIG. 4 is a circuit diagram illustrating the configuration of the ramp signal buffer circuit 131 in a normal drive mode (AD mode).

As illustrated in FIG. 3, the ramp signal buffer circuit 131 includes an input control unit 141, an output control unit 142, a current source 143, an input terminal 144, an output terminal 145, a first capacitor (C1) 146, a second capacitor (C2) 147, a first switch unit 151, a second switch unit 152, a third switch unit 153, a fourth switch unit 154, a first voltage application unit 161, and a second voltage application unit 162.

The input control unit 141, the output control unit 142, and the current source 143 include, for example, a P-type metal-oxide-semiconductor (MOS) transistor. The input terminal 144 is connected to the gate of the MOS transistor constituting the input control unit 141. The input terminal 144 causes a ramp signal output from the ramp signal generation circuit 132 to be input to the gate of the input control unit 141. In a case where the voltage of the ramp signal is higher than or equal to a threshold voltage Vth1 between the gate and the drain of the MOS transistor constituting the input control unit 141, the input control unit 141 enters a conducting state (ON state). In contrast, in a case where the voltage of the ramp signal is lower than the threshold voltage Vth1 between the gate and the drain of the MOS transistor constituting the input control unit 141, the input control unit 141 enters a nonconducting state (OFF state).

The drain of the MOS transistor constituting the output control unit 142 and the output terminal 145 are connected to the source of the input control unit 141. In addition, the drain of the MOS transistor constituting the current source 143 is connected to the drain of the input control unit 141. The input control unit 141 inputs a ramp signal output from the ramp signal generation circuit 132 to the AD converter 133 by electrically connecting the input terminal 144 and the output terminal 145.

The first capacitor 146 and the second capacitor 147 are connected in series between the gate of the output control unit 142 and the gate of the current source 143. The input control unit 141, the output control unit 142, and the first capacitor 146 form a first feedback circuit FB1. The input control unit 141, the current source 143, and the second capacitor 147 form a second feedback circuit FB2.

A power supply is connected to the source of the output control unit 142. A ramp signal input to the input terminal 144 is input to the gate of the output control unit 142 as an alternating current (AC) voltage of the ramp signal via the drain of the input control unit 141 and the first capacitor 146. The output control unit 142 amplifies an output current flowing through the output terminal 145.

The first switch unit 151 turns on or off the connection between the gate of the output control unit 142 and the output terminal 145. The second switch unit 152 turns on or off the connection between the drain of the input control unit 141 and the first and second capacitors 146 and 147. The third switch unit 153 turns on or off the connection of the first voltage application unit 161 to the first feedback circuit FB1. The fourth switch unit 154 turns on or off the connection of the second voltage application unit 162 to the second feedback circuit FB2.

In the reset mode illustrated in FIG. 3, the first switch unit 151, the third switch unit 153, and the fourth switch unit 154 are turned on, and the second switch unit 152 is turned off. That is, by turning on the first switch unit 151, the output control unit 142 is diode-connected and the gate of the output control unit 142 is charged with a voltage Vy. By turning on the third switch unit 153, an external applied voltage Vext from the first voltage application unit 161 is charged with a voltage Vfb between the first capacitor 146 and the second capacitor 147. By turning on the fourth switch unit 154, an external applied voltage Vbias from the second voltage application unit 162 is charged with a voltage Vz applied to the gate of the current source 143.

In the drive mode illustrated in FIG. 4, the first switch unit 151, the third switch unit 153, and the fourth switch unit 154 are turned off, and the second switch unit 152 is turned on. That is, by turning on the second switch unit 152, a signal is fed back from the drain of the input control unit 141 to the gate of the output control unit 142, and the difference between the voltages Vx and Vext is fed back from the drain of the input control unit 141 to the gate of the current source 143.

As a result, an input dynamic range Vin is expressed as follows:

$$Vx - \vert Vth 1 \vert < Vin < Vy + \vert Vth 2 \vert - Vsg 1$$

Accordingly, the larger the difference between Vx and Vy is, the wider the range is. Note that Vsg1 is the voltage between the gate and the source of the MOS transistor constituting the input control unit 141.

### Reason 1 for Necessity of Current Source FB

Here, the reason why feedback to the current source 143 is necessary will be described.

Let Q1 and Q2 denote the charges accumulated in the first capacitor 146 and the second capacitor 147 in the reset mode Φ1, and let Q′1 and Q′2 denote the charges accumulated in the first capacitor 146 and the second capacitor 147 in the drive mode Φ2. Assuming that the charge conservation law holds for Q1 and Q2 and Q′1 and Q′2 (actually, an error occurs for a charge to slightly escape from Vx), the following equations hold:

$$Q 1 + Q 2 = {Q}^{′} 1 + {Q}^{′} 2 \\ C 1 ( Vext - Vy ) + C 2 ( Vext - Vbias ) = C 1 ( Vx - Vy ) + C 2 ( Vx - Vz ) \\ Vz = Vbias + K ( Vx - Vext ) \\ K = ( C 1 + C 2 ) / C 2$$

Here, if (Vx−Vext) is an error voltage, negative feedback (feedback) works to set the error voltage to 0, so that (Vx−Vext) converges to 0. As a result, Vx converges to Vext, and Vz converges to Vbias.

From the above, the following two points can be said.

By applying negative feedback, the drain voltage Vx of the input control unit 141 can be determined by the external applied voltage Vext. In addition, a resultant error in the gate voltage Vz of the current source 143 is minute.

### Reason 2 for Necessity of Current Source FB

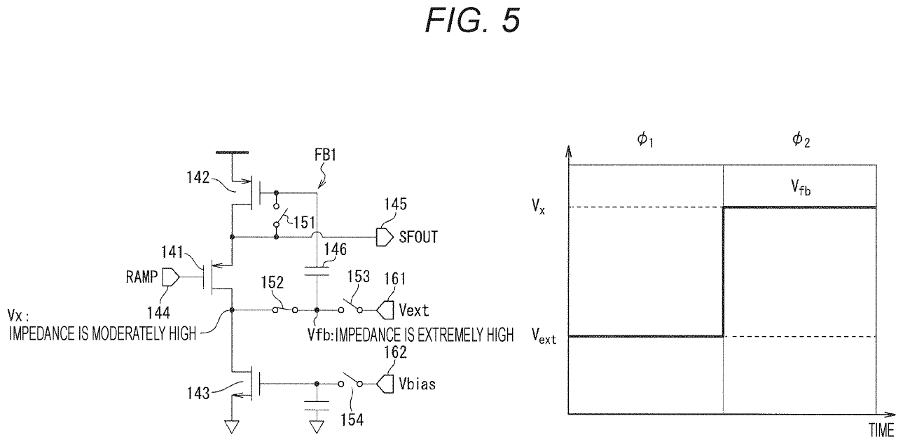

FIG. 5 illustrates a change in the voltage Vfb between the first capacitor 146 and the second capacitor 147 in a case where the second feedback circuit FB2 is not formed.

In the reset mode Φ1, the second switch unit 152 is turned off and the third switch unit 153 is turned on, and the external applied voltage Vext is thereby charged with the voltage Vfb between the first capacitor 146 and the second capacitor 147. In the drive mode Φ2, the second switch unit 152 is turned on and the third switch unit 153 is turned off. As a result, in a case where the voltage Vfb, with which the applied voltage Vext is charged, is short-circuited with the drain voltage Vx of the input control unit 141, the voltage Vfb becomes a voltage close to the drain voltage Vx of the input control unit 141. This is because potential is pulled toward lower impedance.

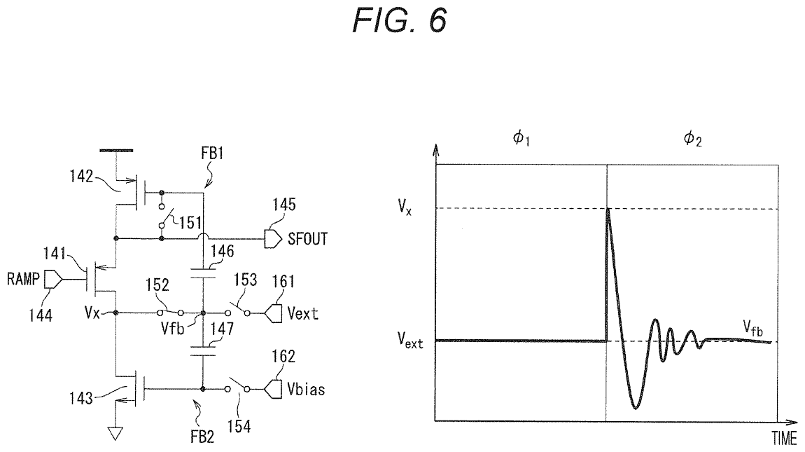

FIG. 6 illustrates a change in the voltage Vfb between the first capacitor 146 and the second capacitor 147 in a case where the second feedback circuit FB2 is formed.

In the reset mode Φ1, the second switch unit 152 is turned off and the third switch unit 153 is turned on, and the external applied voltage Vext is thereby charged with the voltage Vfb between the first capacitor 146 and the second capacitor 147. In the drive mode Φ2, the second switch unit 152 is turned on and the third switch unit 153 is turned off. As a result, in a case where the voltage Vfb, with which the applied voltage Vext is charged, is short-circuited with the drain voltage Vx of the input control unit 141, the voltage Vfb is instantaneously pulled by the drain voltage Vx of the input control unit 141. However, since negative feedback works, the voltage Vfb finally converges to the applied voltage Vext.

### Operation and Effect of First Embodiment

As described above, according to the first embodiment, the first capacitor 146 is inserted into the first feedback circuit FB1, and the second capacitor 147 is inserted into the second feedback circuit FB2, so that only an AC voltage is fed back to the gate of the output control unit 142. This makes it possible to prevent the drain of the input control unit 141 and the gate of the output control unit 142 from being at the same potential in a direct current manner and to secure a wide dynamic range, while maintaining low output impedance.

In addition, according to the first embodiment, a sufficiently wide dynamic range can be secured for applications by using the external applied voltage Vext from the first voltage application unit 161 and the external applied voltage Vbias from the second voltage application unit 162.

### Second Embodiment

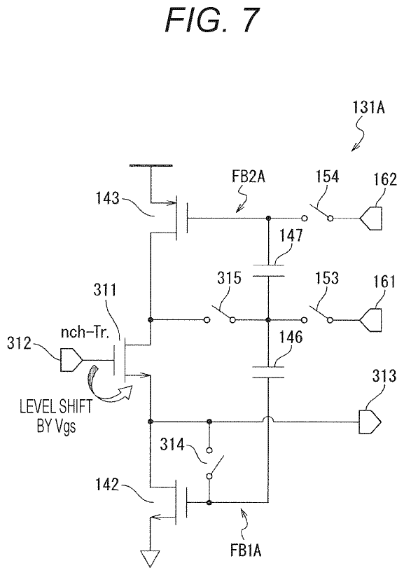

FIG. 7 is a circuit diagram illustrating the configuration of a ramp signal buffer circuit 131A according to a second embodiment of the present disclosure. In FIG. 7, the same components as those in FIGS. 3 and 4 described above are denoted by the same reference signs, and detailed description thereof is omitted.

In the second embodiment of the present disclosure, an input control unit 311 includes, for example, an N-type MOS transistor that is opposite in polarity to a P-type. As a result, the roles of MOS transistors constituting the output control unit 142 and the current source 143 are reversed as compared to those in the case of FIGS. 3 and 4. An input terminal 312 is connected to the gate of the MOS transistor constituting the input control unit 311. In a case where the voltage of a ramp signal is higher than or equal to a threshold voltage between the gate and the source of the MOS transistor constituting the input control unit 311, the input control unit 311 enters a conducting state (ON state). In contrast, in a case where the voltage of the ramp signal is lower than the threshold voltage between the gate and the source of the MOS transistor constituting the input control unit 311, the input control unit 311 enters a nonconducting state (OFF state).

The drain of the MOS transistor constituting the current source 143 is connected to the drain of the input control unit 311. In addition, the drain of the MOS transistor constituting the output control unit 142 and an output terminal 313 are connected to the source of the input control unit 311. The input control unit 311, the current source 143, and the second capacitor 147 form a second feedback circuit FB2A. The input control unit 311, the output control unit 142, and the first capacitor 146 form a first feedback circuit FB1A.

A first switch unit 314 turns on or off the connection between the gate of the output control unit 142 and the output terminal 313. A second switch unit 315 turns on or off the connection between the drain of the input control unit 311 and the first and second capacitors 146 and 147.

In the reset mode, the first switch unit 314, the third switch unit 153, and the fourth switch unit 154 are turned on, and the second switch unit 315 is turned off. That is, by turning on the first switch unit 314, the output control unit 142 is diode-connected and the gate of the output control unit 142 is charged with a voltage Vy. By turning on the third switch unit 153, an external applied voltage Vext from the first voltage application unit 161 is charged with a voltage Vfb between the first capacitor 146 and the second capacitor 147. By turning on the fourth switch unit 154, an external applied voltage Vbias from the second voltage application unit 162 is charged with a voltage Vz applied to the gate of the current source 143.

In the drive mode, the first switch unit 314, the third switch unit 153, and the fourth switch unit 154 are turned off, and the second switch unit 315 is turned on. That is, by turning on the second switch unit 315, a signal is fed back from the drain of the input control unit 311 to the gate of the current source 143, and the difference between the voltages Vy and Vext is fed back from the drain of the input control unit 311 to the gate of the output control unit 142.

### Operation and Effect of Second Embodiment

As described above, according to the second embodiment, similar operation and effect to those of the first embodiment can be achieved.

### Third Embodiment

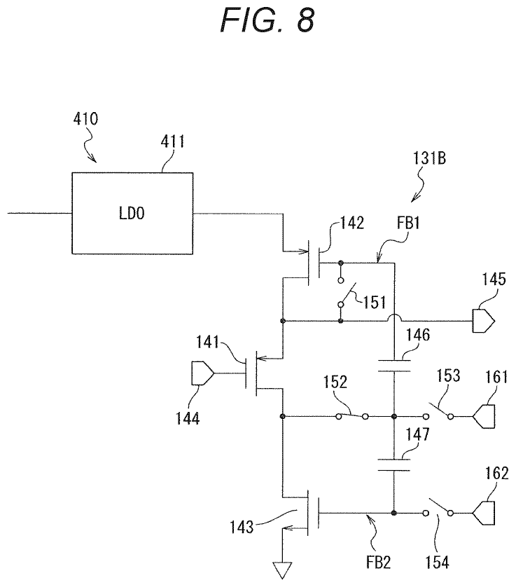

FIG. 8 is a circuit diagram illustrating the configurations of a power supply circuit 410 and a ramp signal buffer circuit 131B according to a third embodiment of the present disclosure. In FIG. 8, the same components as those in FIGS. 3 and 4 described above are denoted by the same reference signs, and detailed description thereof is omitted.

The power supply circuit 410 supplies power necessary for operation of each of the pixel array unit 11, the column processing unit 13 including the ramp signal buffer circuit 131B, and the signal processing unit 16. The power supply circuit 410 according to the fourth embodiment of the present disclosure includes a low drop out (LDO) 411. As an example, the LDO 411 is a direct current (DC) to direct current (DC) converter. The LDO 411 is a component that compensates a power supply rejection ratio (PSRR) of the power supply circuit 410. The power supply rejection ratio of the power supply circuit 410 is the ability of the power supply circuit 410 to remove voltage fluctuation of a power supply VDD in a case where there is a fluctuation (ripple) in the power supply voltage.

That is, the LDO 411 can attenuate the fluctuation amount of the power supply voltage input from the power supply circuit 410 and output a reference signal at a constant voltage level to the input control unit 141, the output control unit 142, and the current source 143.

### Operation and Effect of Third Embodiment

As described above, according to the third embodiment, the power supply rejection ratio can be improved by providing the power supply circuit 410 itself with the LDO 411.

### Fourth Embodiment

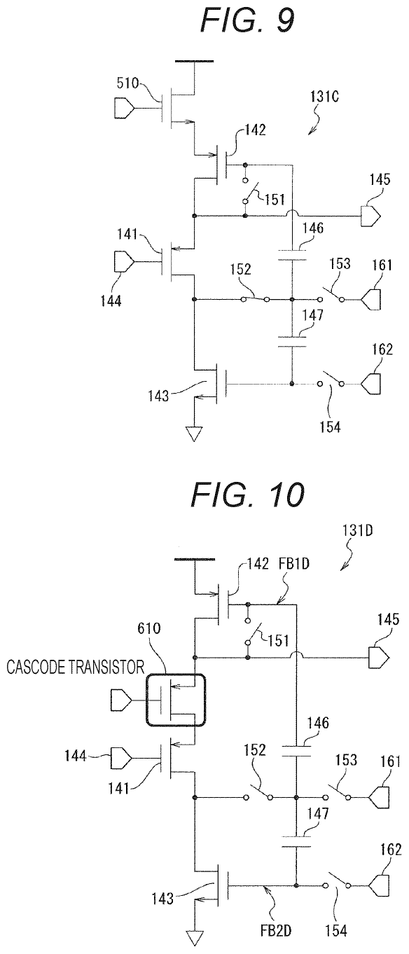

FIG. 9 is a circuit diagram illustrating the configuration of a ramp signal buffer circuit 131C according to a fourth embodiment of the present disclosure. In FIG. 9, the same components as those in FIGS. 3 and 4 described above are denoted by the same reference signs, and detailed description thereof is omitted.

The ramp signal buffer circuit 131C according to the fourth embodiment of the present disclosure includes a source follower circuit 510 connected to a power supply line that supplies power necessary for operation to the input control unit 141, the output control unit 142, and the current source 143. The source follower circuit 510 includes, for example, an N-type MOS transistor. The source of the output control unit 142 is connected to the source of the source follower circuit 510. The power supply line is connected to the drain of the source follower circuit 510.

The source follower circuit 510 can attenuate power supply noise of a power supply voltage input via the drain and output a reference signal at a constant voltage level to the input control unit 141, the output control unit 142, and the current source 143.

### Operation and Effect of Fourth Embodiment

As described above, according to the fourth embodiment, the power supply noise can be attenuated by providing the source follower circuit 510.

### Fifth Embodiment

FIG. 10 is a circuit diagram illustrating the configuration of a ramp signal buffer circuit 131D according to a fifth embodiment of the present disclosure. In FIG. 10, the same components as those in FIGS. 3 and 4 described above are denoted by the same reference signs, and detailed description thereof is omitted.

In the ramp signal buffer circuit 131D according to the fifth embodiment of the present disclosure, a cascode transistor 610 is inserted into a first feedback circuit FB1D formed by the input control unit 141, the output control unit 142, and the first capacitor 146. The cascode transistor 610 includes, for example, a P-type MOS transistor. The source of the input control unit 141 is connected to the drain of the cascode transistor 610. The drain of the output control unit 142 and the output terminal 145 are connected to the source of the cascode transistor 610.

### Operation and Effect of Fifth Embodiment

As described above, according to the fifth embodiment, the loop gain of the first feedback circuit FB1D can be improved by inserting the cascode transistor 610 into the first feedback circuit FB1D.

### Sixth Embodiment

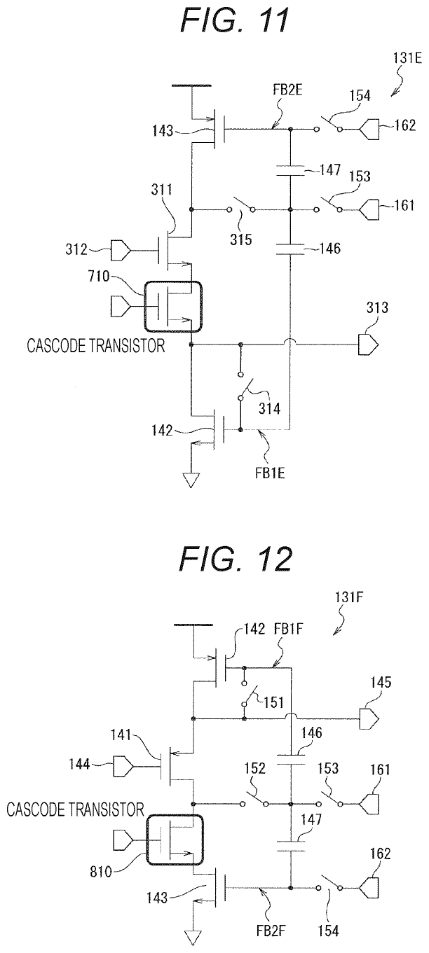

FIG. 11 is a circuit diagram illustrating the configuration of a ramp signal buffer circuit 131E according to a sixth embodiment of the present disclosure. In FIG. 11, the same components as those in FIG. 7 described above are denoted by the same reference signs, and detailed description thereof is omitted.

In the ramp signal buffer circuit 131E according to the sixth embodiment of the present disclosure, a cascode transistor 710 is inserted into a first feedback circuit FB1E formed by the input control unit 311, the output control unit 142, and the first capacitor 146.

The cascode transistor 710 includes, for example, an N-type MOS transistor. The source of the input control unit 141 is connected to the drain of the cascode transistor 710. The drain of the output control unit 142 and the output terminal 313 are connected to the source of the cascode transistor 710.

### Operation and Effect of Sixth Embodiment

As described above, according to the sixth embodiment, the loop gain of the first feedback circuit FB1E can be improved by inserting the cascode transistor 710 into the first feedback circuit FB1E.

### Seventh Embodiment

FIG. 12 is a circuit diagram illustrating the configuration of a ramp signal buffer circuit 131F according to a seventh embodiment of the present disclosure. In FIG. 12, the same components as those in FIGS. 3 and 4 described above are denoted by the same reference signs, and detailed description thereof is omitted.

In the ramp signal buffer circuit 131F according to the seventh embodiment of the present disclosure, a cascode transistor 810 is inserted into a second feedback circuit FB2F formed by the input control unit 141, the current source 143, and the second capacitor 147. The cascode transistor 810 includes, for example, an N-type MOS transistor, and is a component for compensating the linearity of the current source 143.

The drain of the input control unit 141 is connected to the drain of the cascode transistor 810. The drain of the current source 143 is connected to the source of the cascode transistor 810.

### Operation and Effect of Seventh Embodiment

As described above, according to the seventh embodiment, the linearity of the current source 143 can be improved by connecting the cascode transistor 810 between the input control unit 141 and the current source 143.

### Eighth Embodiment

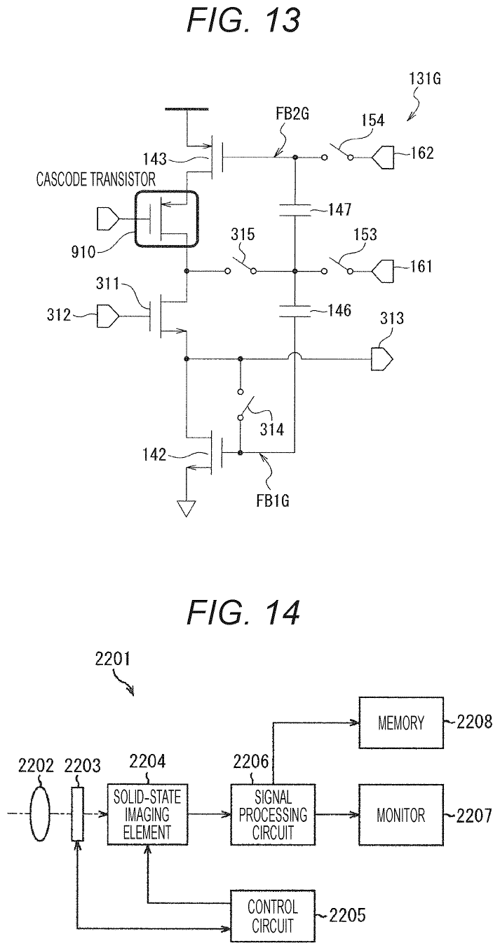

FIG. 13 is a circuit diagram illustrating the configuration of a ramp signal buffer circuit 131G according to an eighth embodiment of the present disclosure. In FIG. 13, the same components as those in FIG. 7 described above are denoted by the same reference signs, and detailed description thereof is omitted.

In the ramp signal buffer circuit 131G according to the eighth embodiment of the present disclosure, a cascode transistor 910 is inserted into a second feedback circuit FB2G formed by the input control unit 311, the current source 143, and the second capacitor 147. The cascode transistor 910 includes, for example, a P-type MOS transistor, and is a component for compensating the linearity of the current source 143.

The drain of the input control unit 311 is connected to the drain of the cascode transistor 910. The drain of the current source 143 is connected to the source of the cascode transistor 910.

### Operation and Effect of Eighth Embodiment

As described above, according to the eighth embodiment, the linearity of the current source 143 can be improved by connecting the cascode transistor 910 between the input control unit 311 and the current source 143.

### Other Embodiments

The present technology has been described as above according to the first to eighth embodiments, but it should not be understood that the description and drawings forming a part of this disclosure limit the present technology. It will be apparent to those skilled in the art that various alternative embodiments, examples, and operation techniques can be included in the present technology when understanding the spirit of the technical content disclosed in the first to eighth embodiments described above. Furthermore, the configurations disclosed in the first to eighth embodiments can be appropriately combined within a range in which no contradiction occurs. For example, configurations disclosed in a plurality of different embodiments may be combined, or configurations disclosed in a plurality of different modifications of the same embodiment may be combined.

### Application Example to Electronic Apparatus

The photodetection device described above can be applied to various electronic apparatuses, for example, imaging devices such as a digital still camera and a digital video camera, a mobile phone with an imaging function, or other apparatuses having an imaging function.

FIG. 14 is a block diagram illustrating a configuration example of an imaging system as an electronic apparatus to which the present technology is applied.

An imaging system 2201 illustrated in FIG. 14 includes an optical system 2202, a shutter device 2203, a solid-state imaging element 2204 as an imaging device, a control circuit 2205, a signal processing circuit 2206, a monitor 2207, and two memories 2208, and can capture a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 is disposed between the optical system 2202 and the solid-state imaging element 2204, and controls a light irradiation period and a light shielding period for the solid-state imaging element 2204 under the control of the control circuit 2205.

The solid-state imaging element 2204 includes a package including the above-described solid-state imaging element. The solid-state imaging element 2204 accumulates signal charges for a certain period according to the light which is formed as an image on the light receiving surface via the optical system 2202 and the shutter device 2203. The signal charges accumulated on the solid-state imaging element 2204 are transferred according to a drive signal (timing signal) supplied from the control circuit 2205.

The control circuit 2205 outputs a drive signal for controlling a transfer operation of the solid-state imaging element 2204 and a shutter operation of the shutter device 2203 to drive the solid-state imaging element 2204 and the shutter device 2203.

The signal processing circuit 2206 performs various types of signal processing on the signal charges output from the solid-state imaging element 2204. An image (image data) obtained by the signal processing circuit 2206 performing the signal processing is supplied to the monitor 2207 to be displayed or supplied to the memories 2208 to be stored (recorded).

Also in the imaging system 2201 configured as described above, the imaging device 1 can be applied instead of the solid-state imaging element 2204 described above.

Note that the present disclosure can also have the following configurations.
(1) A buffer circuit including:
a first transistor having a gate to which an input signal is input;
a current source connected to one terminal of the first transistor;
a second transistor connected to another terminal of the first transistor;
an output terminal connected to the one terminal or the another terminal of the first transistor; and
first and second capacitors provided between the current source and a gate of the second transistor,
the first transistor, the second transistor, and the first capacitor forming a first feedback circuit,
the first transistor, the current source, and the second capacitor forming a second feedback circuit.
(2) The buffer circuit according to (1), further including a first voltage application unit that applies a predetermined first voltage to the first feedback circuit.
(3) The buffer circuit according to (2), further including a second voltage application unit that applies a second voltage different from the first voltage to the second feedback circuit.
(4) The buffer circuit according to (3), further including:
a first switch unit that turns on or off a connection between the gate of the second transistor and the output terminal;

a second switch unit that turns on or off a connection between the terminal to which the output terminal is not connected of the first transistor and the first and second capacitors;

a third switch unit that turns on or off a connection between the first voltage application unit and the first and second capacitors; and
a fourth switch unit that turns on or off a connection between the second voltage application unit, and the second capacitor and the current source,
in which in a reset mode, the first switch unit, the third switch unit, and the fourth switch unit are turned on and the second switch unit is turned off, and
in a drive mode, the first switch unit, the third switch unit, and the fourth switch unit are turned off and the second switch unit is turned on.
(5) The buffer circuit according to (1), in which the first transistor includes a first conductivity type, and
the output terminal is connected between the first transistor and the second transistor.
(6) The buffer circuit according to (5), further including:
a first voltage application unit that applies a predetermined first voltage to the first feedback circuit;
a second voltage application unit that applies a second voltage different from the first voltage to the second feedback circuit;
a first switch unit that turns on or off a connection between the gate of the second transistor and the output terminal;
a second switch unit that turns on or off a connection between the terminal to which the output terminal is not connected of the first transistor and the first and second capacitors;
a third switch unit that turns on or off a connection between the first voltage application unit and the first and second capacitors; and
a fourth switch unit that turns on or off a connection between the second voltage application unit, and the second capacitor and the current source,
in which in a reset mode, the first switch unit, the third switch unit, and the fourth switch unit are turned on and the second switch unit is turned off, and
in a drive mode, the first switch unit, the third switch unit, and the fourth switch unit are turned off and the second switch unit is turned on.
(7) The buffer circuit according to (5), in which a cascode transistor is connected between the first transistor and the output terminal.
(8) The buffer circuit according to (5), in which a cascode transistor is connected between the first transistor and the current source.
(9) The buffer circuit according to (5), in which the first transistor includes a second conductivity type that is opposite in polarity to the first conductivity type, and
the output terminal is connected between the first transistor and the second transistor.
(10) The buffer circuit according to (9), further including:
a first voltage application unit that applies a predetermined first voltage to the first feedback circuit;
a second voltage application unit that applies a second voltage different from the first voltage to the second feedback circuit;
a first switch unit that turns on or off a connection between the second transistor and the output terminal;
a second switch unit that turns on or off a connection between the terminal to which the output terminal is not connected of the first transistor and the first and second capacitors;
a third switch unit that turns on or off a connection between the first voltage application unit and the first and second capacitors; and
a fourth switch unit that turns on and off a connection between the second voltage application unit, and the second capacitor and the current source,
in which in a reset mode, the first switch unit, the third switch unit, and the fourth switch unit are turned on and the second switch unit is turned off; and
in a drive mode, the first switch unit, the third switch unit, and the fourth switch unit are turned off and the second switch unit is turned on.
(11) The buffer circuit according to (9), in which a cascode transistor is connected between the first transistor and the output terminal.
(12) The buffer circuit according to (9), in which a cascode transistor is connected between the first transistor and the current source.
(13) The buffer circuit according to (1), further including a source follower circuit that is connected to a power supply line that supplies power necessary for operation to the first transistor, the second transistor, and the current source, and outputs a reference signal at a constant voltage level to the first transistor, the second transistor, and the current source.
(14) An imaging device including:
a pixel array unit including a plurality of pixels allowed to generate a pixel signal according to light incident from outside;
a buffer circuit;
a signal processing unit that compares an output signal of the buffer circuit with a pixel signal output from each of the plurality of pixels and generates image data on the basis of a comparison result; and
a power supply circuit that supplies power necessary for operation of each of the pixel array unit, the buffer circuit, and the signal processing unit,
the buffer circuit including:
a first transistor having a gate to which an input signal is input;
a current source connected to one terminal of the first transistor;
a second transistor connected to another terminal of the first transistor;
an output terminal connected to the one terminal or the another terminal of the first transistor; and
first and second capacitors provided between the current source and a gate of the second transistor,
the first transistor, the second transistor, and the first capacitor forming a first feedback circuit,
the first transistor, the current source, and the second capacitor forming a second feedback circuit.
(15) The imaging device according to (14), in which the power supply circuit has a function of outputting a reference signal at a constant voltage level to the first transistor, the second transistor, and the current source.

### REFERENCE SIGNS LIST

1 Imaging device
11 Pixel array unit
12 Vertical drive unit
13 Column processing unit
14 Horizontal drive unit
15 System control unit
16 Signal processing unit
17 Data storage unit
18 Pixel drive line
19 Vertical signal line
20 Pixel signal reading mechanism
110 Pixel
131, 131A, 131B, 131C, 131D, 131E, 131G Ramp signal buffer circuit
132 Ramp signal generation circuit
133 AD converter
134 Comparator
135 Counter
141, 311 Input control unit
142 Output control unit
143 Current source
144, 312 Input terminal
145, 313 Output terminal
146 First capacitor (C1)
147 Second capacitor (C2)
151, 314 First switch unit
152, 315 Second switch unit
153 Third switch unit
154 Fourth switch unit
161 First voltage application unit
162 Second voltage application unit
201 First module
202 Second module
211, 212 Source follower circuit
410 Power supply circuit
411 LDO
510 Source follower circuit
610, 710, 810, 910 Cascode transistor
2201 Imaging system
2202 Optical system
2203 Shutter device
2204 Solid-state imaging element
2205 Control circuit
2206 Signal processing circuit
2207 Monitor
2208 Memory

What is claimed is:

1. A buffer circuit, comprising:
a first transistor having a gate to which an input signal is input;
a current source connected to one terminal of the first transistor;
a second transistor connected to another terminal of the first transistor;
an output terminal connected to the one terminal or the another terminal of the first transistor; and
first and second capacitors provided between the current source and a gate of the second transistor,
the first transistor, the second transistor, and the first capacitor forming a first feedback circuit,
the first transistor, the current source, and the second capacitor forming a second feedback circuit.

2. The buffer circuit according to claim 1, further comprising a first voltage application unit that applies a predetermined first voltage to the first feedback circuit.

3. The buffer circuit according to claim 2, further comprising a second voltage application unit that applies a second voltage different from the first voltage to the second feedback circuit.

4. The buffer circuit according to claim 3, further comprising:
a first switch unit that turns on or off a connection between the gate of the second transistor and the output terminal;
a second switch unit that turns on or off a connection between the terminal to which the output terminal is not connected of the first transistor and the first and second capacitors;
a third switch unit that turns on or off a connection between the first voltage application unit and the first and second capacitors; and
a fourth switch unit that turns on or off a connection between the second voltage application unit, and the second capacitor and the current source,
wherein in a reset mode, the first switch unit, the third switch unit, and the fourth switch unit are turned on and the second switch unit is turned off, and
in a drive mode, the first switch unit, the third switch unit, and the fourth switch unit are turned off and the second switch unit is turned on.

5. The buffer circuit according to claim 1, wherein the first transistor comprises a first conductivity type, and
the output terminal is connected between the first transistor and the second transistor.

6. The buffer circuit according to claim 5, further comprising:
a first voltage application unit that applies a predetermined first voltage to the first feedback circuit;
a second voltage application unit that applies a second voltage different from the first voltage to the second feedback circuit;
a first switch unit that turns on or off a connection between the gate of the second transistor and the output terminal;
a second switch unit that turns on or off a connection between the terminal to which the output terminal is not connected of the first transistor and the first and second capacitors;
a third switch unit that turns on or off a connection between the first voltage application unit and the first and second capacitors; and
a fourth switch unit that turns on or off a connection between the second voltage application unit, and the second capacitor and the current source,
wherein in a reset mode, the first switch unit, the third switch unit, and the fourth switch unit are turned on and the second switch unit is turned off, and
in a drive mode, the first switch unit, the third switch unit, and the fourth switch unit are turned off and the second switch unit is turned on.

7. The buffer circuit according to claim 5, wherein a cascode transistor is connected between the first transistor and the output terminal.

8. The buffer circuit according to claim 5, wherein a cascode transistor is connected between the first transistor and the current source.

9. The buffer circuit according to claim 5, wherein the first transistor comprises a second conductivity type that is opposite in polarity to the first conductivity type, and
the output terminal is connected between the first transistor and the second transistor.

10. The buffer circuit according to claim 9, further comprising:
a first voltage application unit that applies a predetermined first voltage to the first feedback circuit;
a second voltage application unit that applies a second voltage different from the first voltage to the second feedback circuit;
a first switch unit that turns on or off a connection between the second transistor and the output terminal;
a second switch unit that turns on or off a connection between the terminal to which the output terminal is not connected of the first transistor and the first and second capacitors;
a third switch unit that turns on or off a connection between the first voltage application unit and the first and second capacitors; and
a fourth switch unit that turns on and off a connection between the second voltage application unit, and the second capacitor and the current source,
wherein in a reset mode, the first switch unit, the third switch unit, and the fourth switch unit are turned on and the second switch unit is turned off; and
in a drive mode, the first switch unit, the third switch unit, and the fourth switch unit are turned off and the second switch unit is turned on.

11. The buffer circuit according to claim 9, wherein a cascode transistor is connected between the first transistor and the output terminal.

12. The buffer circuit according to claim 9, wherein a cascode transistor is connected between the first transistor and the current source.

13. The buffer circuit according to claim 1, further comprising a source follower circuit that is connected to a power supply line that supplies power necessary for operation to the first transistor, the second transistor, and the current source, and outputs a reference signal at a constant voltage level to the first transistor, the second transistor, and the current source.

14. An imaging device, comprising:
a pixel array unit comprising a plurality of pixels allowed to generate a pixel signal according to light incident from outside;
a buffer circuit;
a signal processing unit that compares an output signal of the buffer circuit with a pixel signal output from each of the plurality of pixels and generates image data on a basis of a comparison result; and
a power supply circuit that supplies power necessary for operation of each of the pixel array unit, the buffer circuit, and the signal processing unit,
the buffer circuit comprising:
a first transistor having a gate to which an input signal is input;
a current source connected to one terminal of the first transistor;
a second transistor connected to another terminal of the first transistor;
an output terminal connected to the one terminal or the another terminal of the first transistor; and
first and second capacitors provided between the current source and a gate of the second transistor,
the first transistor, the second transistor, and the first capacitor forming a first feedback circuit,
the first transistor, the current source, and the second capacitor forming a second feedback circuit.

15. The imaging device according to claim 14, wherein the power supply circuit has a function of outputting a reference signal at a constant voltage level to the first transistor, the second transistor, and the current source.
